(19) United States
(12) Patent Application Publication
(10) Pub. No.: US 2003/0227091 A1
(43) Pub. Date: Dec. 11, 2003

(54) Plating metal caps on conductive interconnect for wirebonding

(76) Inventors: Nishant Sinha, Boise, ID (US); Dinesh Chopra, Boise, ID (US)

Correspondence Address: DICKSTEIN SHAPIRO MORIN & OSHINSKY LLP, 2101 L STREET NW, WASHINGTON, DC, 20037-1526, US

(21) Appl. No.: 10/162,673

(22) Filed: Jun. 6, 2002

(51) Int. Cl. H01L 23/48; H01L 29/40; H01L 21/4763

(52) U.S. Cl. 257/762; 257/751; 438/627; 438/687; 257/767

(57) ABSTRACT

A method of forming a conductive interconnect, preferably a copper interconnect, comprising a metal cap formed thereover. The metal cap is preferably comprises silver, gold, cobalt, nickel-tungsten, cobalt-tungsten, silver-tungsten or nickel. The conductive interconnect is fabricated by forming a substrate having a trench formed therein, forming a barrier layer over the substrate and within the trench, forming a conductive layer over the barrier layer and within the trench, planarizing the conductive layer to an upper surface of the barrier layer, recessing the conductive layer below an upper surface of the barrier layer, and forming a metal layer over the conductive layer via electroplating.

### FIELD OF THE INVENTION

The present invention relates to the field of electrochemical deposition, and in particular to a method of electroplating a metal cap over a conductive interconnect.

### BACKGROUND OF THE INVENTION

The performance characteristics and reliability of integrated circuits have become increasingly dependent on the structure and attributes of the vias and interconnects which are used to carry electronic signals between semiconductor devices on integrated circuits or chips. Advances in the fabrication of integrated circuits have resulted in increases in the density, number of semiconductor devices contained on a typical chip, and speed. Interconnect structure and formation technology has not advanced as rapidly, and is increasingly becoming a limitation on the signal speed of integrated circuits.

Typically the preferred metal for use in the construction of integrated circuit interconnects has been aluminum. Aluminum is widely used because it is inexpensive, relatively easy to etch, and adheres well to inter layer dielectrics (ILDs), such as silicon dioxide. Disadvantages of aluminum include significant electromigration effects, susceptibility to humidity-induced corrosion, and the tendency to “cold creep”. “Cold creep” is a process that creates cracks or spaces between the interconnect layer and the ILD due to large variances in the coefficient of thermal expansion between the two materials.

The disadvantages of aluminum interconnects have become more pronounced as the geometry of integrated circuits continues to shrink. Chip designers have attempted to utilize different materials to construct an interconnect system having the chemical and mechanical properties which will complement and enhance smaller and faster circuit systems. The ideal interconnect material is inexpensive, easily patterned and has low resistivity, minimal electromigration effects, high corrosion resistance, and a similar coefficient of thermal expansion to the ILD and substrate material. Metals possessing these characteristics include gold, silver, and copper, and research has generally focused on these three metals as new via and interconnect materials.

Copper is the most attractive material for use in integrated circuits because of its desirable chemical and mechanical properties. It is inexpensive, easily processed, and an excellent conductor with a resistivity of 1.73 microOhms per centimeter. Copper also has fewer electromigration effects than aluminum and can therefore carry a higher maximum current density, permitting a faster rate of electron transfer. The high melting point and ductility of copper produce far less cold creep during the semiconductor fabrication process than many other metals, including aluminum.

In a conventional aluminum wirebonding process, the bond pad on the chip surface may be easily attached to aluminum or gold wires by standard and highly automated tools. With the recent introduction of interconnects formed of copper, the aluminum or gold wirebonding processes have been performed by direct fabrication on the copper bond pads. A direct wirebond on copper pads cannot be performed, since a wirebond formed on pure copper by either aluminum or gold wires is subjected to corrosion, oxidation and thermal diffusion problems. Over time copper tends to oxidize and form a copper oxide, thus changing the conductive characteristics of the copper interconnect to resistor characteristics and decreasing solderability of the interconnect. Copper also has poor surface adhesion characteristics to most of the suitable wirebonding materials, and thus, it has been difficult to provide a copper interconnect with improved resistance to corrosion and electromigration and at the same time providing good surface adhesion.

Since a direct wirebond to copper pads is unreliable and subject to fail, attempts have been made to cap the upper surface of the copper interconnect with a suitable material. Accordingly, since gold to aluminum wirebonding is well known, physical vapor deposited (PVD) aluminum caps have been used for gold to aluminum wirebonding. However, this process is costly and inefficient.

Another attempt to overcome the problems associated with copper interconnects, have included providing a less corrosive metal having good copper and wirebonding material adhesion properties. One such attempt uses electroless plating to form an electroless metal film, such as an electroless silver film, over the copper interconnect. However, the use of electroless films is disadvantageous due to the instability of the electroless bath and electroless film chemistry. Electroless plating is also disadvantageous due to the poor adherence qualities and light sensitivity of electroless films. Furthermore, electroless plating of different bond pads requires different surface potentials due to the different grounding characteristics of the bond pads. For instance, bond pads that are more positively charged etch more copper during activation and result in non-uniform discontinuously plated films.

Accordingly there is a need for a method of forming a copper interconnect that is protected from copper oxidation, has improved corrosion resistance and provides improved surface adherence qualities for copper and wirebonding materials. Furthermore there is a need for a method of fabricating a metal layer over an interconnect that provides improved metal to copper adherence, uniform metal deposition over the interconnects and which can be used to produce a good bond with wire and other bonding materials.

### BRIEF SUMMARY OF THE INVENTION

The present invention provides a method of forming a metal cap over a conductive interconnect to both protect the conductive interconnect and provide a good material for bonding, e.g. wirebonding. The metal cap is preferably gold, nickel, cobalt, nickel-tungsten, cobalt-tungsten, silver-tungsten, or more preferably silver. The interconnect preferably comprises copper. The metal cap is formed by electroplating a metal, such as silver, over a conductive interconnect, such as a copper interconnect. More particularly, the method comprises forming an insulating layer having a trench formed therein; forming a barrier layer over the insulating layer and within the trench; plating a copper interconnect over the barrier layer and within the trench; planarizing the copper interconnect to the level of the barrier layer; recessing the copper interconnect to a level below an upper surface of the barrier layer; electroplating a silver layer over the copper interconnect; and planarizing the silver layer to form a silver cap over the copper interconnect.

These and other features and advantages of the invention will be more apparent from the following detailed description, which is provided in connection with the accompanying drawings, which illustrate exemplary embodiments of the invention.

### BRIEF DESCRIPTION OF THE DRAWINGS

FIG. 1 is a cross-sectional view of a portion of an integrated circuit structure undergoing fabrication according to a preferred embodiment of the invention;

FIG. 2 shows the substrate of FIG. 1 at a fabrication step subsequent to that shown in FIG. 1;

FIG. 3 shows the substrate of FIG. 1 at a fabrication step subsequent to that shown in FIG. 2;

FIG. 4 shows the substrate of FIG. 1 at a fabrication step subsequent to that shown in FIG. 3;

FIG. 5 shows the substrate of FIG. 1 at a fabrication step subsequent to that shown in FIG. 4;

FIG. 6 shows the substrate of FIG. 1 at a fabrication step subsequent to that shown in FIG. 5;

FIG. 7 shows the substrate of FIG. 1 at a fabrication step subsequent to that shown in FIG. 6;

FIGS. 8A and 8B show the substrate of FIG. 1 at a fabrication step subsequent to that shown in FIG. 7; and

FIG. 9 illustrates a processor system having one or more memory devices that contains an integrated circuit structure according to the present invention.

### DETAILED DESCRIPTION OF THE INVENTION

In the following detailed description, reference is made to various specific embodiments in which the invention may be practiced. These embodiments are described with sufficient detail to enable those skilled in the art to practice the invention, and it is to be understood that other embodiments may be employed, and that structural and electrical changes may be made without departing from the spirit or scope of the invention.

The terms “substrate” used in the following description may include any semiconductor-based structure that has an exposed semiconductor surface. Structure must be understood to include silicon, silicon-on insulator (SOI), silicon-on sapphire (SOS), doped and undoped semiconductors, epitaxial layers of silicon supported by a base semiconductor foundation, and other semiconductor structures. The semiconductor need not be silicon-based. The semiconductor could be silicon-germanium, or germanium. When reference is made to a “substrate” in the following description, previous process steps may have been utilized to form regions or junctions in or on the base semiconductor or foundation.

Referring now to the drawings, where like elements are designated by like reference numerals, FIGS. 1 through 8 illustrate an exemplary embodiment of a method of fabricating an integrated circuit having an interconnect comprising a metal cap according to the invention.

The process begins subsequent to the formation of the integrated circuit structure 10. However, the invention can be applied at any level of integrated circuit fabrication. For purposes of simplification the invention is descriptive with reference to an upper metalization layer, for example, the top most metalization layer, where bond pads are required for later use in a wirebonding process. As such, FIGS. 1 through 8 illustrate a fabricated integrated circuit structure 10 having a base substrate 11, a plurality of fabricated layers collectively shown by 13 and upper conductive areas 21 to which an interconnect in accordance with the invention will be connected. Although not shown, it is to be understood that the integrated circuit structure 10 may contain transistors, capacitors, word lines, bit lines, active areas, or the like fabricated in the layer 13 over substrate 11. As shown in FIG. 1 interconnect trenches 22 are patterned in an insulating layer 20 provided over the structure 10. The insulating layer 20 preferably comprises tetraethylorthosilicate (TEOS) oxide. At least some of the openings 22 are provided at locations where interconnects will electrically communicate with conductive areas 21 provided in the uppermost portion of structures 10.

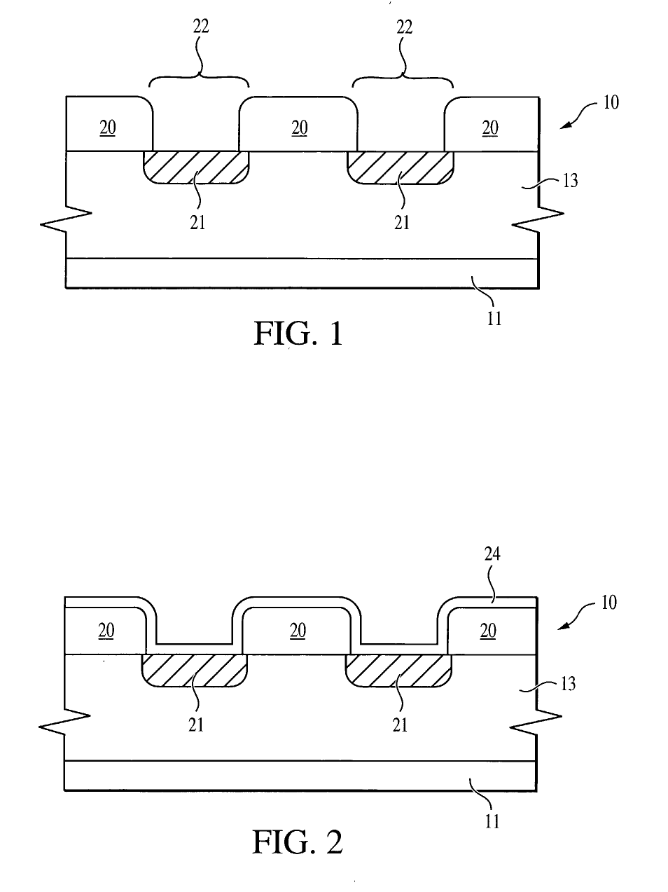

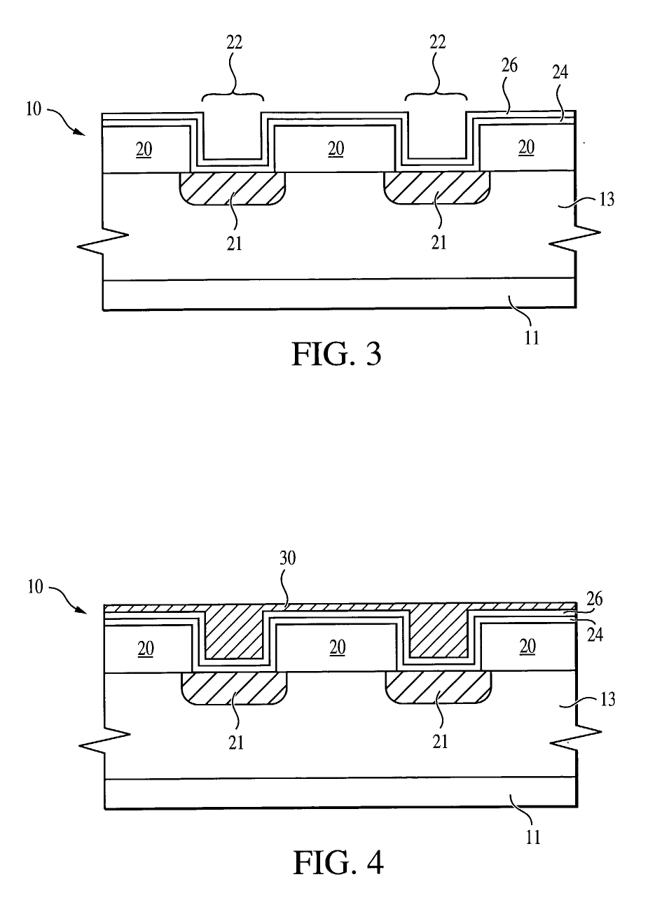

Referring now to FIG. 2, a barrier layer 24, is blanket deposited over the surface of the structure 10 so that it overlies the insulating layer 20 and lines the interconnect trenches 22. Although, the barrier layer 24 is usually used to prevent copper from diffusing into the insulating layer 20 and the structure 10 and/or into conductive areas 21, there may be instances where no barrier layer 24 is necessary. The barrier layer 24 is preferably formed of tantalum(Ta) or tantalum-nitride (TaN). However, any suitable material for preventing copper diffusion may be used, for example, titanium, titanium-nitride, tungsten-nitride, tungsten-tantalum, tantalum silicon nitride, or other ternary compounds. The barrier layer 24 is preferably deposited via physical vapor deposition (PVD) but may be deposited via any suitable technique, for example chemical vapor deposition (CVD). The barrier layer 24 is preferably between about 200 Angstroms to about 600 Angstroms thick, and more preferably about 500 Angstroms.

Referring now to FIG. 3, an optional copper seed layer 26, is formed on the surface of the barrier layer 24 and in trenches 22 by PVD or CVD. The principle purpose of the copper seed layer 26, is to give a nucleating and conductive surface for subsequent electroplating, wherein the trenches are filled. This process is well know n in the art. In a preferred embodiment the copper seed layer 26 is either deposited via CVD or PVD.

Now referring to FIG. 4, a conductive interconnect 30, preferably comprising copper, is formed over the structure 10 and in the interconnect trenches 22. However, the conductive interconnect 30 may be formed of any suitable material. The conductive interconnect 30 may also be formed by an electrochemical deposition process such as electroplating. Any suitable electroplating or electroless plating process, as is well known in the art, may be used. A combination of the two may also be performed as desired for certain applications.

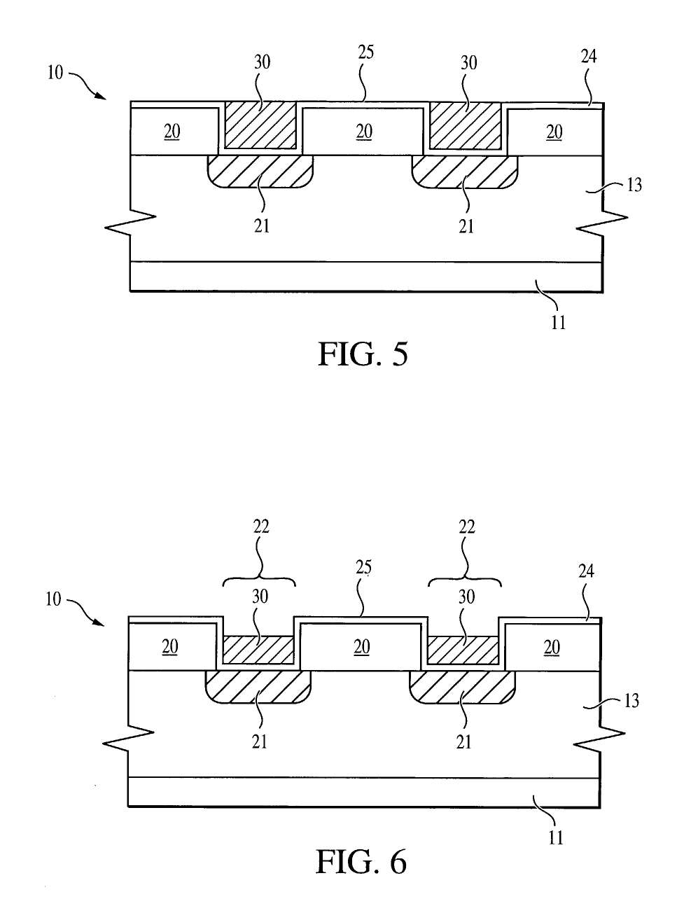

Referring now to FIG. 5, the conductive interconnect 30 (which is hereinafter shown for convenience as a single layer that encompasses the copper seed layer 26) is planarized or CMP'd to stop on an upper surface 25 of the barrier layer 24.

Referring now to FIG. 6, the conductive interconnect 30 is further planarized to dish or recess the copper to a suitable distance below the upper surface 25 of the barrier layer 24 Any suitable method for recessing the copper may be used. For instance, the conductive interconnect 30 may be selectively over-polished, chemical mechanically planarized, wet etched, or dry etched to recess the copper within the trenches 22.

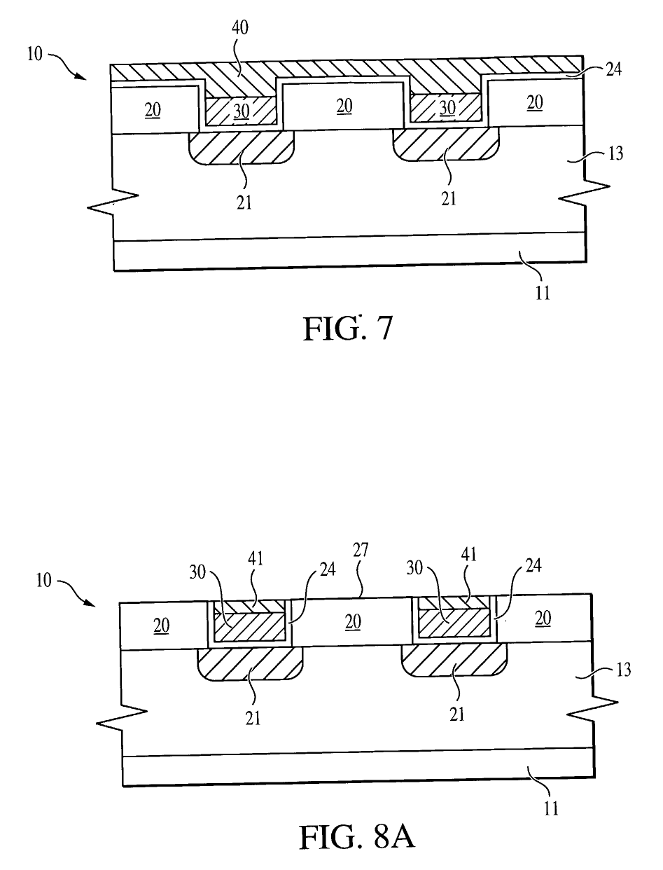

Referring now to FIG. 7, a metal layer 40 is then formed over the substrate by an electroplating process. The metal layer may comprise any suitable metal. Preferably the metal layer comprises, gold, nickel, cobalt, nickel-tungsten, cobalt-tungsten, gold-tungsten, or even more preferably silver. Electroplating processes are well know in the art and any suitable electroplating process may be used. For example, the FIG. 6 structure may be immersed in a suitable electrolytic bath or sprayed with a suitable plating solution. Then a suitable electric current is provided to the substrate via the barrier layer 24 to provide continuous plating of the barrier layer 24 and the copper interconnect 30. Electroless deposition may also be used.

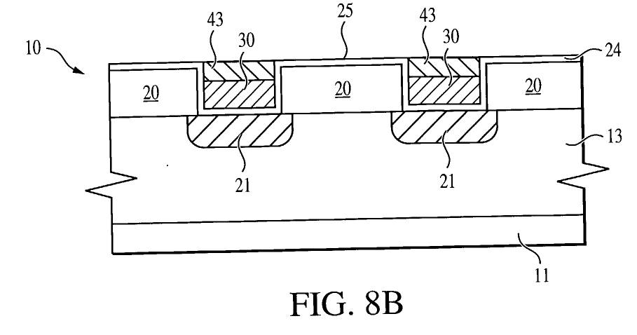

Subsequent the electroplating process of the metal layer, conventional processing methods such as planarization of the FIG. 7 structure 10 to isolate the metal layer 40 into individual metal caps (as shown in FIGS. 8A and 8B), may then be used to create a functional circuit from the integrated circuit structure 10.

Referring now to FIG. 8A, the metal layer 40 and barrier layer 24 may then be planarized or electrochemically polished down to an upper surface 27 of the insulating layer 20 to form metal caps 41.

Referring now to FIG. 8B, alternatively, the metal layer 40 may be planarized or electrochemically polished down to an upper surface 25 of the barrier layer 24 to form metal caps 43.

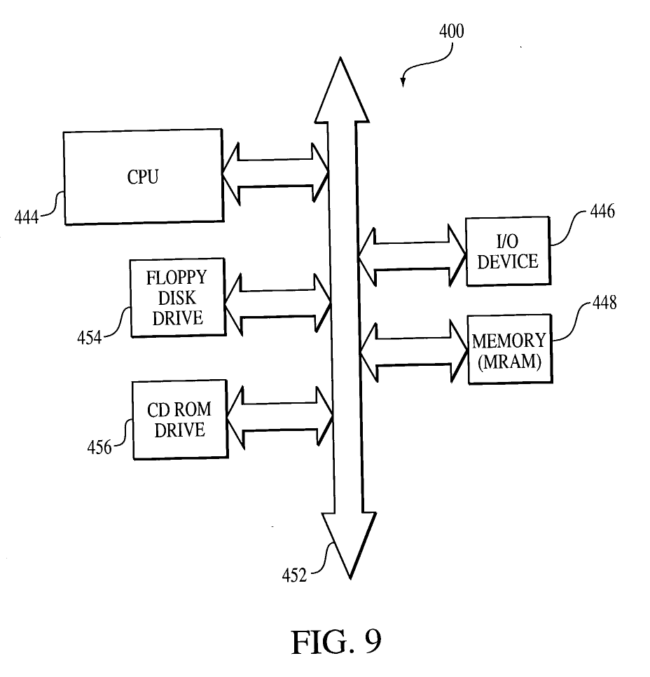

FIG. 9 illustrates a typical processor-based system 400, which includes an integrated circuit 448, which employs a conductive interconnect fabricated in accordance with the invention. A processor system, such as a computer system, generally comprises a central processing unit (CPU) 444, such as a microprocessor, a digital signal processor, or other programmable digital logic devices, which communicates with an input/output (I/O) device 446 over a bus 452. The memory 448 communicates with the system over bus 452 typically through a memory controller.

In the case of a computer system, the processor system may include peripheral devices such as a floppy disk drive 454 and a compact disc (CD) ROM drive 456, which also communicate with CPU 444 over the bus 452. Integrated circuit 448 may include one or more conductive interconnects. If desired, the integrated circuit 448 may be combined with the processor, for example CPU 444, in a single integrated circuit.

One of the advantages of the invention is the use of a metal cap over a copper interconnect. This protects the copper interconnect from corrosion and oxidation. Also, as it is difficult to wirebond directly to copper, the use of a silver, gold or nickel cap according to the present invention provides for more efficient wirebonding processes. Furthermore, since some pads are deeper into the integrated circuit than others, electroplating the metal directly onto the conductive interconnect allows for a more uniform deposition across a structure having varied pad depths.

The above description and drawings are only to be considered illustrative of exemplary embodiments, which achieve the features and advantages of the invention. Modification and substitutions to specific process conditions and structures can be made without departing from the spirit and scope of the invention. Accordingly, the invention is not to be considered as being limited by the foregoing description and drawings, but is only limited by the scope of the appended claims.

What is claimed as new and desired to be protected by Letters Patent of the United States is:

1. A method of plating a conductive interconnect of an integrated circuit, said method comprising:
forming an insulating layer over a fabricated structure;
providing an opening in said insulating layer;
forming a conductive layer over said insulating layer and within said opening;
removing portions of said conductive layer to form a conductive area within said opening;
recessing said conductive area within said opening; and
forming a metal layer over said recessed conductive area within said opening.

2. The method of claim 1 further comprising forming a barrier layer over said insulating layer and within said opening before said conductive layer is formed.

3. The method of claim 2 wherein said act of recessing said conductive area comprises a wet etch process.

4. The method of claim 2 wherein said act of recessing said conductive area comprises chemical mechanical planarization.

5. The method of claim 2 wherein said act of recessing said conductive area comprises a dry etch process.

6. The method of claim 2 further comprising planarizing said metal layer to an upper surface of said barrier layer.

7. The method of claim 2 further comprising planarizing said metal layer and said barrier layer to an upper surface of said insulating layer.

8. The method of claim 2 further comprising electrochemically polishing said metal layer to an upper surface of said barrier layer.

9. The method of claim 2 further comprising electrochemically polishing said metal layer and said barrier layer to an upper surface of said insulating layer.

10. The method of claim 1 wherein said metal layer is a barrier layer.

11. The method of claim 1 wherein said conductive layer comprises copper.

12. The method of claim 11 wherein said metal layer comprises silver.

13. The method of claim 11 wherein said metal layer comprises gold.

14. The method of claim 11 wherein said metal layer comprises cobalt.

15. The method of claim 11 wherein said metal layer comprises nickel-tungsten.

16. The method of claim 11 wherein said metal layer comprises cobalt-tungsten.

17. The method of claim 11 wherein said metal layer comprises silver-tungsten.

18. The method of claim 11 wherein said metal layer comprises nickel.

19. The method of claim 11 wherein said barrier layer comprises tantalum.

20. The method of claim 11 wherein said barrier layer comprises titanium.

21. The method of claim 11 wherein said barrier layer comprises titanium-nitride.

22. The method of claim 11 wherein said barrier layer comprises tantalum-nitride.

23. The method of claim 11 wherein said barrier layer comprises tungsten-nitride.

24. The method of claim 11 wherein said barrier layer comprises tungsten-tantalum.

25. The method of claim 11 wherein said barrier layer comprises tantalum silicon nitride.

26. The method of claim 11 wherein said barrier layer comprises a ternary compound.

27. The method of claim 11 wherein said insulating layer comprises TEOS.

28. The method of claim 1 further comprising depositing a seed layer over said insulating layer and within said opening before forming said conductive layer.

29. The method of claim 1 wherein said act of forming said conductive layer is an electroplating step.

30. The method of claim 1 wherein said act of forming said conductive layer is an electroless plating step.

31. The method of claim 1 wherein said act of forming said metal layer comprises electroplating said metal layer.

32. The method of claim 1 wherein said act of forming said metal layer comprises electroless deposition of said metal layer.

33. The method of claim 2 wherein said barrier layer is formed to have a thickness of between about 200 to about 600 Angstroms.

34. The method of claim 33 wherein said barrier layer is formed to have a thickness of about 500 Angstroms.

35. A method of fabricating a metal cap over a copper interconnect, comprising the steps of:
forming a copper interconnect recessed within an area lined with a barrier layer; and forming a metal cap over said recessed copper interconnect by electroplating.

36. The method of claim 35 wherein said metal cap comprises silver.

37. The method of claim 35 wherein said metal cap comprises gold.

38. The method of claim 35 wherein said metal cap comprises nickel.

39. The method of claim 35 wherein said metal layer comprises cobalt.

40. The method of claim 35 wherein said metal layer comprises nickel-tungsten.

41. The method of claim 35 wherein said metal layer comprises cobalt-tungsten.

42. The method of claim 35 wherein said metal layer comprises silver-tungsten.

43. The method of claim 35 wherein said barrier layer comprises tantalum.

44. The method of claim 35 further comprising depositing a seed layer before forming said conductive layer.

45. The method of claim 44 wherein said seed layer comprises copper.

46. The method of claim 35 further comprising the step of planarizing said metal cap to an upper surface of said barrier layer.

47. The method of claim 35 further comprising the step of planarizing said metal cap and said barrier layer.

48. The method of claim 35 wherein said barrier layer is formed to have a thickness of between about 200 Angstroms to about 600 Angstroms.

49. The method of claim 48 wherein said barrier layer is formed to have a thickness of about 500 Angstroms.

50. A method of forming a copper interconnect for a semiconductor circuit, comprising the steps of:
providing a semiconductor structure having devices formed thereon;
forming an insulating layer over said semiconductor structure;
forming a trench in said insulating layer;
forming a barrier layer over an upper surface of said structure and within said trench;
forming a copper layer over an upper surface of said barrier layer and within said trench;
recessing said copper layer to a level below said upper surface of said barrier layer; and
forming a metal layer over an upper surface of said copper layer and within said trench.

51. A processor-based system comprising:
a processor;
an integrated circuit coupled to said processor, said integrated circuit including a plurality of copper interconnects, each of said interconnects comprising: an insulating layer formed over a fabricated structure; a trench formed in said insulating layer; a barrier layer formed over an upper surface of said structure and within said trench; a recessed copper layer formed over an upper surface of said barrier layer and within said trench; said recessed copper layer being formed to a level below said upper surface of said barrier layer; and a metal layer formed over an upper surface of said recessed copper layer and within said trench.

52. The system of claim 51 wherein said metal layer comprises silver.

53. The system of claim 51 wherein said metal layer comprises gold.

54. The system of claim 51 wherein said metal layer comprises nickel.

55. The method of claim 51 wherein said metal layer comprises cobalt.

56. The method of claim 51 wherein said metal layer comprises nickel-tungsten.

57. The method of claim 51 wherein said metal layer comprises cobalt-tungsten.

58. The method of claim 51 wherein said metal layer comprises silver-tungsten.

59. The system of claim 51 further comprising the step of planarizing said metal layer to said upper surface of said barrier layer.

60. The system of claim 51 further comprising the step of planarizing said metal layer and said barrier layer to an upper surface of said insulating layer.

61. The system of claim 51 wherein said barrier layer has a thickness between about 200 Angstroms to about 600 Angstroms.

62. The system of claim 61 wherein said barrier layer has a thickness of about 500 Angstroms

63. The system of claim 51 wherein said barrier layer comprises tantalum.

64. The system of claim 51 wherein said metal layer is formed by electroplating.

65. A conductive interconnect of an integrated circuit comprising:
an insulating layer having an opening therein formed over a fabricated structure;
a copper layer formed over said insulating layer and within said opening, wherein a portion of said copper layer formed within said opening is recessed; and
an electroplated metal layer formed over said copper layer and within said recessed portion of said copper layer, whereby said electroplated metal layer is planarized to an upper surface of said insulating layer.

66. The interconnect of claim 65 further comprising a barrier layer formed between said insulating layer and said copper layer and within said opening.

67. The interconnect of claim 66 wherein said barrier layer comprises tantalum.

68. The interconnect of claim 66 wherein said barrier layer comprises titanium.

69. The interconnect of claim 66 wherein said barrier layer comprises titanium-nitride.

70. The interconnect of claim 66 wherein said barrier layer comprises tantalum-nitride.

71. The interconnect of claim 66 wherein said barrier layer comprises tungsten-nitride.

72. The interconnect of claim 66 wherein said barrier layer comprises tungsten-tantalum.

73. The interconnect of claim 66 wherein said barrier layer comprises tantalum silicon nitride.

74. The interconnect of claim 66 wherein said barrier layer comprises a ternary compound.

75. The interconnect of claim 66 wherein said insulating layer comprises TEOS.

76. The interconnect of claim 65 further comprising depositing a seed layer formed over said insulating layer and within said opening.

77. The interconnect of claim 66 wherein said barrier layer has a thickness of between about 200 to about 600 Angstroms.

78. The interconnect of claim 77 wherein said barrier layer has a thickness of about 500 Angstroms.

79. The interconnect of claim 66 wherein said metal layer comprises silver.

80. The interconnect of claim 66 wherein said metal layer comprises gold.

81. The interconnect of claim 66 wherein said metal layer comprises nickel.

82. The interconnect of claim 66 wherein said metal layer comprises cobalt.

83. The interconnect of claim 66 wherein said metal layer comprises nickel-tungsten.

84. The interconnect of claim 66 wherein said metal layer comprises cobalt-tungsten.

85. The interconnect of claim 66 wherein said metal layer comprises silver-tungsten.

86. A conductive interconnect of an integrated circuit comprising:
an insulating layer having an opening therein formed over a fabricated structure;
a barrier layer formed over said insulating layer and within said opening;
a copper layer formed over said barrier layer and within said opening, wherein a portion of said copper layer formed within said opening is recessed; and
an electroplated metal layer formed over said copper layer and within said recessed portion of said copper layer, whereby said electroplated metal layer is planarized to an upper surface of said barrier layer.

87. The interconnect of claim 86 wherein said barrier layer comprises tantalum.

88. The interconnect of claim 86 wherein said barrier layer comprises titanium.

89. The interconnect of claim 86 wherein said barrier layer comprises titanium-nitride.

90. The interconnect of claim 86 wherein said barrier layer comprises tantalum-nitride.

91. The interconnect of claim 86 wherein said barrier layer comprises tungsten-nitride.

92. The interconnect of claim 86 wherein said barrier layer comprises tungsten-tantalum.

93. The interconnect of claim 86 wherein said barrier layer comprises tantalum silicon nitride.

94. The interconnect of claim 86 wherein said barrier layer comprises a ternary compound.

95. The interconnect of claim 86 wherein said insulating layer comprises TEOS.

96. The interconnect of claim 86 further comprising a seed layer formed over said barrier layer and within said opening.

97. The interconnect of claim 86 wherein said barrier layer has a thickness of between about 200 to about 600 Angstroms.

98. The interconnect of claim 97 wherein said barrier layer has a thickness of about 500 Angstroms.

99. The interconnect of claim 86 wherein said metal layer comprises silver.

100. The interconnect of claim 86 wherein said metal layer comprises gold.

101. The interconnect of claim 86 wherein said metal layer comprises nickel.

102. The method of claim 86 wherein said metal layer comprises cobalt.

103. The method of claim 86 wherein said metal layer comprises nickel-tungsten.

104. The method of claim 86 wherein said metal layer comprises cobalt-tungsten.

105. The method of claim 86 wherein said metal layer comprises silver-tungsten.

106. A structure for wirebonding comprising:
an insulating layer on a substrate;
at least one trench formed in said insulating layer;
a barrier layer formed over said insulating layer and within said trench;
a recessed copper layer formed over said barrier layer and within said trench; and
an electroplated silver layer formed over said copper layer and within said trench.

107. The structure of claim 106 wherein said electroplated silver layer is planarized to an upper surface of said barrier layer.

108. The structure of claim 106 wherein said electroplated silver layer and said barrier layer are planarized to an upper surface of said insulating layer.

109. The structure of claim 106 wherein said barrier layer comprises tantalum.

110. The structure of claim 106 wherein said insulating layer comprises TEOS.

111. The structure of claim 106 further comprising a seed layer formed over said barrier layer and within said opening.

112. The structure of claim 106 wherein said barrier layer has a thickness of between about 200 to about 600 Angstroms.

113. The structure of claim 112 wherein said barrier layer has a thickness of about 500 Angstroms.

114. A structure for wirebonding comprising:
an insulating layer on a substrate;
at least one trench formed in said insulating layer;
a barrier layer formed over said insulating layer and within said trench;
a recessed copper layer formed over said barrier layer and within said trench; and
an electroplated gold layer formed over said copper layer and within said trench.

115. The structure of claim 114 wherein said electroplated gold layer is planarized to an upper surface of said barrier layer.

116. The structure of claim 114 wherein said electroplated gold layer and said barrier layer are planarized to an upper surface of said insulating layer.

117. The structure of claim 114 wherein said barrier layer comprises tantalum.

118. The structure of claim 114 wherein said insulating layer comprises TEOS.

119. The structure of claim 114 further comprising a seed layer formed over said barrier layer and within said opening.

120. The structure of claim 114 wherein said barrier layer has a thickness of between about 200 to about 600 Angstroms.

121. The structure of claim 120 wherein said barrier layer has a thickness of about 500 Angstroms.

122. A structure for wirebonding comprising:
an insulating layer on a substrate;
at least one trench formed in said insulating layer;
a barrier layer formed over said insulating layer and within said trench;
a recessed copper layer formed over said barrier layer and within said trench; and
an electroplated layer comprising nickel formed over said copper layer and within said trench.

123. The structure of claim 122 wherein said electroplated layer is planarized to an upper surface of said barrier layer.

124. The structure of claim 122 wherein said electroplated layer and said barrier layer are planarized to an upper surface of said insulating layer.

125. The structure of claim 122 wherein said barrier layer comprises tantalum.

126. The structure of claim 122 wherein said insulating layer comprises TEOS.

127. The structure of claim 122 further comprising a seed layer formed over said barrier layer and within said opening.

128. The structure of claim 122 wherein said barrier layer has a thickness of between about 200 to about 600 Angstroms.

129. The structure of claim 128 wherein said barrier layer has a thickness of about 500 Angstroms.
